(19) United States
(12) Patent Application Publication
(10) Pub. No.: US 2009/0033186 A1
(43) Pub. Date: Feb. 5, 2009

(54) ENCLOSURE PROVIDING IMPROVED COOLING FOR A HEAT-GENERATING DEVICE

(75) Inventor: Robert Dallas Ricker, Middletown, DE (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Palo Alto, CA (US)

(21) Appl. No.: 11/832,044

(22) Filed: Aug. 1, 2007

(51) Int. Cl. F24F 7/007; F04F 3/00; H05K 5/02

(52) U.S. Cl. 312/236; 417/148

(57) ABSTRACT

An enclosure includes interconnected panels defining an internal space. The panels define an air inlet for admitting cooling air to the enclosure and an air outlet for exhausting cooling air from the enclosure. The panels configure the internal space to promote a linear air flow velocity near the inlet (or outlet) that is greater than a respective velocity near the outlet (or inlet) for a given volumetric flow rate of air through the enclosure. A portion of a cover panel may be angularly oriented to define an increasing transverse cross sectional area between the inlet and outlet, to cause air flowing into the enclosure to change in linear velocity as it traverses the enclosure. The cover panel may have separate portions positioned at different heights such that the cross-sectional areas near the outlet and inlet differ. The fan may be angularly oriented for better removal of heated cooling air.

### FIELD OF THE INVENTION

The present invention relates generally to enclosures for devices that generate heat during normal operation, and more particularly to an enclosure providing enhanced cooling.

### DISCUSSION OF THE RELATED ART

Pumps, particularly vacuum pumps, are widely used in laboratory environments to permit the operation of analytical equipment and to conduct experimental procedures. For example, mass spectroscopy equipment requires strong vacuums for proper operation. Although pumps are essential to many analytical and experimental tasks, the pumps are often relatively loud, which is often undesirable, particularly in laboratories. Pumps can be isolated within small enclosures to reduce ambient noise. An exemplary enclosure is disclosed in U.S. Patent Application Publication No. 2006/00170314.

Although isolation within a small enclosure may be effective for reducing ambient noise, such isolation can cause overheating due to heat generated by the pump during normal operation. Various other devices, such as computers, communications equipment, and various mechanical and electronic devices similarly generate undesirable heat during operation. There exists a need for an enclosure for housing devices that provides improved cooling for the device.

### SUMMARY OF THE INVENTION

The present invention provides an enclosure for housing a device that provides enhanced cooling for the device housed therein. The enclosure includes panels interconnected to define an internal space configured to receive the device. The panels define an air inlet for admitting cooling air to the enclosure and an air outlet for exhausting cooling air from the enclosure. The panels collectively configure the internal space to promote an air flow velocity adjacent the inlet that is greater than a respective air flow velocity adjacent the outlet for a fixed volumetric flow rate of air passing through the enclosure from the inlet to the outlet. The slowing of the linear velocity of the cooling air adjacent the outlet increases heat transfer by the cooling air that offsets a decrease in cooling capacity of the cooling air. This decrease in cooling capacity is due to warming of the cooling air as it absorbs heat while travelling through the enclosure from the inlet toward the outlet.

In certain embodiments, the enclosure includes a cover panel having a portion that is angularly oriented relative to a horizontal plane, and defines an internal space having an increasing transverse cross sectional area between the inlet and outlet. The increasing cross-sectional area causes air flowing into said enclosure through said inlet to slow as it approaches said outlet. The angularly oriented portion may be positioned substantially directly above a heat dissipating surface of the device to allow heated cooling air to rise further away from the heat dissipation surface.

The cover panel may have different portions positioned at different heights above the device to define spaces having different cross sectional areas transverse to a flow path between the inlet and outlet, such that the cross-sectional area is greater closer to the outlet.

The enclosure may include a cooling fan operable to draw cooling air through the inlet and toward the outlet. The cooling fan may have a blade rotatable about an axis angularly oriented relative to a horizontal plane. One or more cooling fans may be supported on a planar or a non-planar panel. The angularly oriented fan may allow for better removal of heated cooling air, e.g. by mechanically augmenting the natural convective flow of the heated cooling air.

### BRIEF DESCRIPTION OF THE DRAWINGS

Embodiments of the present invention are described below by way of example with reference to the following drawings in which:

FIG. 1 is a front perspective view of an enclosure for housing a heat-generating device, in accordance with an exemplary embodiment of the present invention;

FIG. 2 is a rear view of the enclosure of FIG. 1;

FIG. 3 is a side cross-sectional view of the enclosure of FIG. 1, taken along line 3-3 of FIG. 1;

FIG. 4 is a perspective view of an exemplary frame of the enclosure of FIG. 1; and

FIG. 5-9 are side views of alternative exemplary embodiments of an enclosure for housing a device;

FIGS. 10 and 11 are side and end views, respectively, of another alternative exemplary embodiment of an enclosure for housing a device; and

FIGS. 12 and 13 are side and end views, respectively, of yet another alternative exemplary embodiment of an enclosure for housing a device.

### DETAILED DESCRIPTION

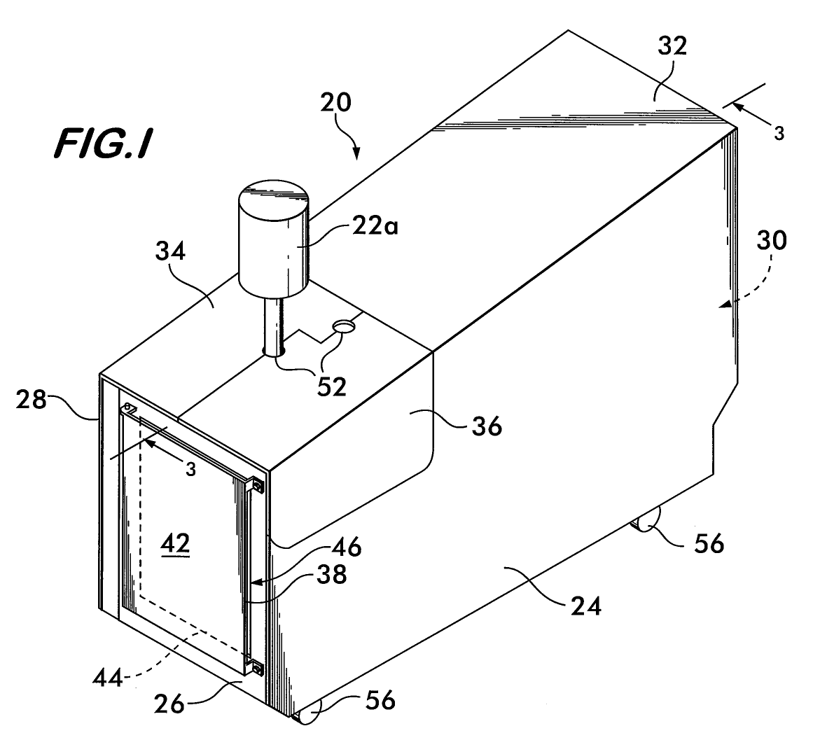

The present invention provides an enclosure for housing a device, such as a vacuum pump or other pump, that generates undesired heat, i.e., thermal waste, during normal operation. In accordance with the present invention, the novel enclosure is specially configured to promote cooling of the device while it is operating within the enclosure. Various embodiments of the enclosure are discussed below with reference to FIGS. 1-13, and in the exemplary context of use of the enclosure to house a vacuum pump, for illustrative purposes only.

Referring now to Figures. 1-4, an enclosure 20 containing a vacuum pump 22 is shown. The enclosure 20 is suitable for housing a vacuum pump 22, while reducing ambient noise generated by the vacuum pump during its operation. The vacuum pump 22 can be used, for example, in mass spectrometry, lyophilizers, and vacuum ovens. The enclosure is specially-configured in accordance with the present invention to promote cooling of the pump it houses, as discussed in greater detail below.

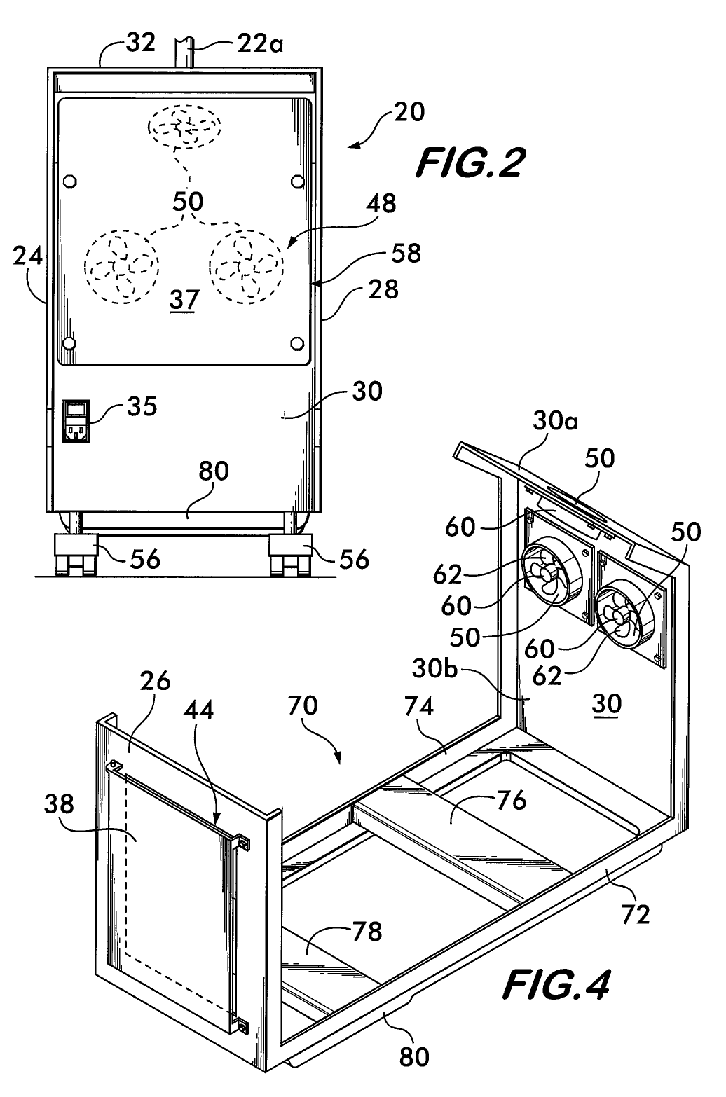

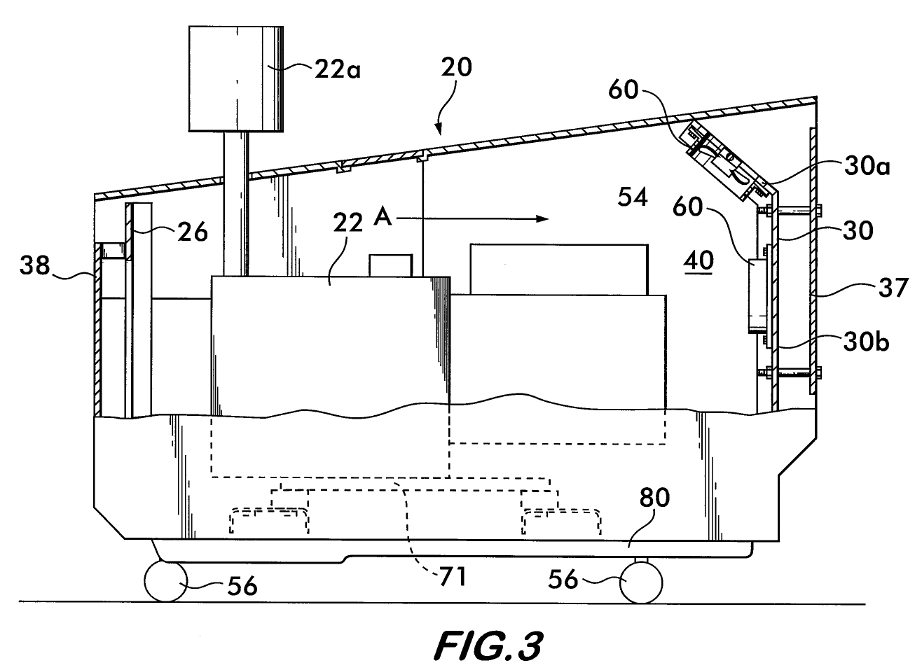

Referring now to FIGS. 1 and 2, the enclosure 20 includes interconnected body panels, namely side panels 24, 26, 28, 30 and bottom panel 80, that substantially surround the vacuum pump. The lower body panel 80 may be a lubricant collection pan, as shown in FIGS. 2 and 3. The enclosure 20 includes also a cover panel 32 connected to the body panels. In certain embodiments the cover panel 32, and one or more of the body panels, e.g., panels 24, 28, are integrally formed as a unit, e.g. as a single piece of formed sheet metal. However, in other implementations the cover panel 32 and body panels 24, 26, 28, 30 and 80 are formed as separate members, and then joined.

The cover panel 32 and body panels 24, 26, 28, 30, 80 cooperate to define an interior space 40 into which the vacuum pump 22 may be placed, as best shown in FIG. 3.

At least one of the panels defines an air inlet for admitting cooling air into the enclosure. At least one of the panels defines an air outlet for exhausting cooling air from the enclosure. Preferably, the inlet and outlet are positioned toward opposite ends of the enclosure. For example, in the exemplary embodiment of FIGS. 1-4, the inlet 42 is defined at least in part by an opening 44 in the front panel 26, or along other openings in the enclosure 20, such as from beneath the enclosure 20 or from gaps between the panels, as best shown in FIG. 1. Further, in this exemplary embodiment, the outlet 48 is defined at least in part by at least one opening 50 in the rear panel 30, as best shown in FIG. 2. Accordingly, an air flow path is defined by the panels between the inlet and the outlet, as shown approximately at A in FIG. 3.

In accordance with an embodiment of the present invention, at least a portion of the cover panel 32 is angularly oriented relative to a horizontal plane. As used herein, “angularly oriented” means having an inner surface that is oriented at an acute or an obtuse angle, i.e., not parallel or perpendicular to, a horizontal plane, such as the horizontal plane of a floor or other surface on which the enclosure will be supported during normal operation of the enclosed pump. Accordingly, the angularly oriented portion of the cover panel 32 defines an upper boundary of the internal space 40 that rises relative to the horizontal plane, and thus permits heated cooling air to rise as it traverses the enclosure 20, as best shown in FIG. 3. An exemplary cover panel 32, in which the entire cover panel 32 is substantially planar, is shown in FIGS. 1-4.

In addition, cover panel 32 defines an internal space 40 having an increasing transverse cross sectional area. As used herein, a transverse cross-sectional area is a cross-sectional area transverse to a direction of air flow from the inlet toward the outlet. In one embodiment, the transverse cross-sectional area is generally greater near the outlet than it is near the inlet. In other embodiments, the transverse cross-sectional area is generally greater near the inlet than it is near the outlet. Applicable principles of fluid mechanics generally provide that for a given volumetric flow rate, cross-sectional area and flow velocity vary inversely. Accordingly, the increasing of the transverse cross-sectional area of the internal space toward the outlet 48 causes cooling air flowing into the enclosure through the inlet 42 to slow as it approaches the outlet 48, as best shown in FIG. 3.

This slowing of the cooling air provides increased time for heat transfer to the cooling air, and thus for enhanced cooling of the heat-generating pump within the enclosure. In accordance with applicable thermal conductivity principles, the rate of heat transfer by a cooling air is proportional to a difference in temperatures between the cooling air and a heat-dissipating surface. Cooling air drawn from ambient has a lowest relative temperature as it enters the heat-laden enclosure. Accordingly, the difference in temperature between the cooling air and the heat-dissipating surfaces of the pump is greatest adjacent the inlet 42. Accordingly, this greatest difference in temperature provides for a relatively high heat transfer rate, and provides for enhanced heat transfer (cooling) even as the cooling air moves quickly through the enclosure.

As the cooling air absorbs dissipated heat and flows toward the outlet 48, its temperature rises, and the difference in temperature between the heated cooling air and the pump's heat dissipating surfaces decreases. Accordingly, this lesser difference in temperature provides for a relatively lower heat transfer rate. Because the enclosure is specially configured to cause the cooling air to flow more slowly toward the outlet, the time period over which the heated cooling air may absorb dissipated heat is lengthened as its temperature rises. This increases heat transfer for cooling air absorbing heat at a lower heat transfer rate, and thus results in better cooling as compared with a faster flow of the heated cooling air. Accordingly, the slowing of the cooling air effectively compensates, at least partially, for the lower heat transfer rate that is due to the lesser difference in temperatures resulting from warming of the cooling air as it traverses the enclosure from the inlet 42 to the outlet 48. As a result, the cooling air can absorb more heat than if the flow rate had remained constant through the enclosure 20, providing improved overall heat transfer and improved cooling of the enclosed pump.

Generally, pumps that generate undesired heat, or thermal waste, have heat dissipating surfaces 54, that are either purpose-specific, such as cooling fins, or incidental, such as an oil pan or crank case cover, that are relative “hot spots” at which thermal waste is concentrated. At such locations, temperature tends to be highest and heat dissipation tends to be greatest. In certain embodiments, at least a portion of the cover panel 32 is constructed and/or positioned to be angularly oriented and/or elevated relative to other portions at a location disposed substantially directly above the heat dissipating surface 54, as shown in FIG. 3. Positioning this portion substantially directly above the heat dissipating surface 54 directs rising heated air upwardly, away from the heat dissipating surface 54, which tends to be replaced with cooler cooling air having a greater capacity for cooling. For example, an angularly oriented portion of the cover panel 32 may be positioned “substantially directly above” the heat dissipating surface by positioning at least a portion of the angularly oriented portion within 30 degrees from a vertical plane from any points directly above such heat dissipating surface 54 when the pump 22 is mounted within the enclosure 20 and the enclosure 20 is positioned upright on a surface in the intended normal operating condition. As shown in FIGS. 1-4, a portion of the angularly oriented cover panel 32 is positioned substantially directly above the heat dissipating surface 54 of the pump 22.

A single cooling fan can be used to either exhaust air from the enclosure 20 or to draw air into the enclosure 20. In other words, the cooling fan is operable to draw cooling air through the inlet and cause it to flow toward the outlet. Alternatively, two or more cooling fans are used to both draw in air and to exhaust air. Preferably, two or more cooling fans are used to exhaust cooling air from the enclosure. The exemplary embodiment of FIGS. 1-4 includes three cooling fans 60 mounted on the rear panel 30 adjacent the openings 50 forming the outlet, as shown in FIGS. 2 and 4. Any suitable conventional cooling fan may be used for this purpose, as will be appreciated by those skilled in the art.

In certain embodiments, the panels including the inlet and outlet are parts of a frame 70 onto which the pump 22 can be mounted. In the exemplary embodiment of FIGS. 1-4, the front and rear panels 26, 30 are parts of the frame 70, as shown in FIG. 4. In the depicted embodiment, frame 70 includes first and second side members 72, 74 and first and second cross members 76, 78 to which the pump may optionally be bolted or otherwise secured.

In certain embodiments, the panel on which the cooling fan is supported, such as rear panel 30 in the exemplary embodiment of FIGS. 1-4, is non-planar and includes first and second substantially planar portions 30a, 30b joined at an oblique angle, as best shown in FIG. 4. As compared with a substantially planar, substantially vertical panel, such a non-planar panel provides additional area for mounting a cooling fan, e.g. to permit mounting of a greater number of cooling fans than a planar, vertical member would permit. In the example of FIGS. 1-4, the first substantially planar portion 30a supports a cooling fan 60 adjacent the outlet 48, and toward an upper portion of the enclosure. Additionally, the second substantially planar portion 30b supports additional cooling fans 60 adjacent the outlet 48. This arrangement permits mounting of a greater number of like-sized cooling fans nearer to the top of the enclosure 20, to facilitate exhausting of heated cooling air where it is likely the hottest.

Optionally, the front panel 26 includes a door 38 providing an opening to the front of a pump 22 placed within the enclosure, as best shown in FIG. 1. In such an embodiment, cooling air can be drawn into the enclosure 20 through the opening 44 via a gap 46 around the front door 38 of the enclosure 20.

In certain embodiments, the enclosure 20 is constructed to permit the flow of cooling air streams in or out of the enclosure 20 while also limiting the escape of noise from the enclosure 20, as best shown in FIG. 2. The volume of noise escaping from the back of enclosure 20 is limited in certain embodiments by placing a baffle 37 over the opening(s) 50 in the enclosure 20. In certain embodiments, the baffle 37 includes a substantially flat sheet of material (such as plastic or metal) that overlies the opening(s) 50 beneath it. In such an embodiment, cooling air can be exhausted from the enclosure 20 through the opening(s) 50 via a gap 58 between the baffle 37 and the panel 30. Optionally, the rear of the enclosure 20 may include a junction 35 for connecting the enclosure 20, pump 22 and/or cooling fans 60 to a power source.

In certain embodiments, the enclosure 20 is constructed such that additional access is easily gained into the enclosure 20 by removing one or more access panels 34, 36 that form at least a part of the body panels 24, 28 and/or cover panel 32, as shown in FIGS. 1 and 3. The access panels may define ports 52 allowing hoses, vacuum lines, etc. to extend into the enclosure 20, and also to allow portions 22a of a pump to extend out of the enclosure 20, as necessary.

The enclosure 20 depicted in the embodiment shown in FIG. 1 is mounted on a plurality of casters 56. The casters 56 permit the enclosure 20 to be easily moved to different locations, and to be readily stored in a convenient location, such as under a laboratory bench. In some implementations the casters 56 can be locked, thereby preventing unintentional rolling of the enclosure. In other implementations no casters are used.

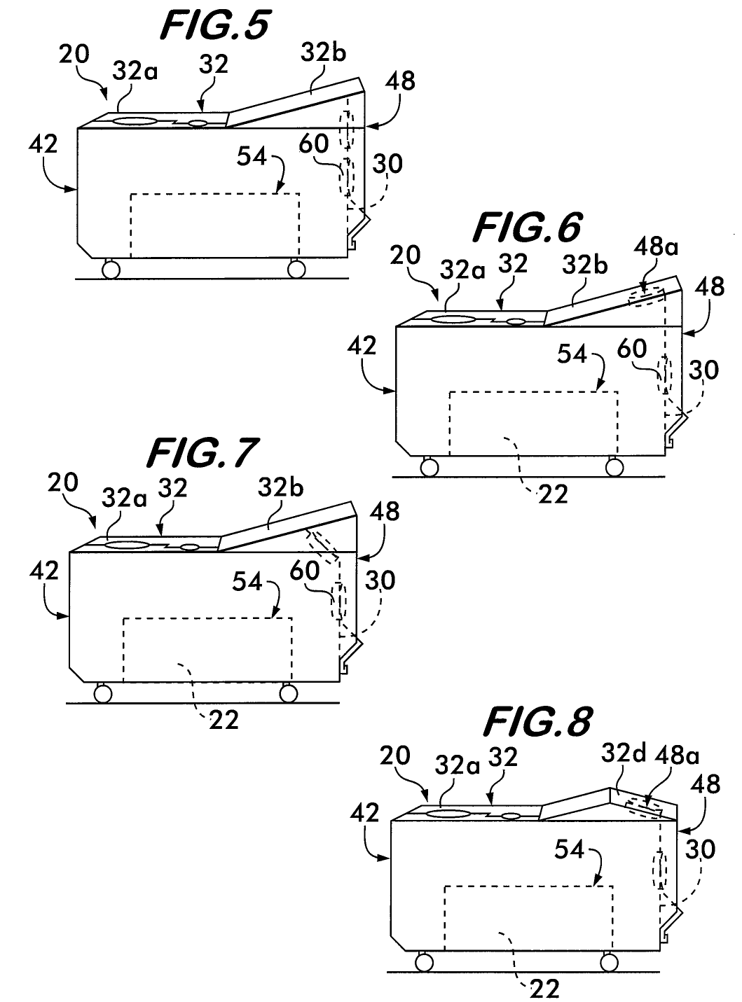

Additional embodiments in accordance with the present invention are shown in FIGS. 5-13. These exemplary enclosures are similar to that of FIGS. 1-4, and may include one or more of the features discussed above. The exemplary enclosures of FIGS. 5-13 are shown in simplified form to emphasize certain salient features of these alternative embodiments, which are discussed below.

Referring now to FIG. 5, an alternative embodiment of an enclosure 20 is shown in which a portion 32b of the cover panel 32 is angularly oriented relative to a horizontal plane and defines an internal space having an increasing transverse cross sectional area between the inlet 42 and the outlet 48. Unlike the embodiment of FIGS. 1-4, the cover panel 32 is not substantially planar, and only a portion 32b of the cover panel 32 is angularly oriented; the remaining portion 32a of the cover panel 32 is substantially parallel to a horizontal plane, and/or is oriented at an angle different from that of the first portion 32a. Additionally, for illustrative purposes only, the exemplary rear panel 30 is shown as substantially planar. Alternatively, the rear panel 30 is non-planar, as shown in FIGS. 1-4. In this embodiment, the cooling fan 60 may be mounted to exhaust air that has risen above the first portion 32a, and may be mounted entirely above the first portion 32a, if desired. The angularly oriented second portion 32b of the cover panel 32 is disposed substantially directly above the heat dissipating surface 54.

Referring now to FIG. 6, an embodiment is shown that is similar to that of FIG. 5. Accordingly, at least a portion 32b of the cover panel 32 is angularly oriented, and the cross-sectional area increases toward the outlet 48 such that air flowing into the enclosure 20 slows as it approaches the outlet 48. Unlike FIG. 5, there is an outlet 48a positioned in the cover panel 32. A cooling fan 60 may be supported adjacent this outlet 48a. Accordingly, the cooling fan 60 exhausts air that has risen above the first portion 32a, and may be mounted entirely above the first portion 32a, if desired. This embodiment promotes exhausting of the hottest air from the region of the enclosure that is likely to be hottest. Additional outlets 48 and cooling fans 60 are provided on the rear panel 30 in this embodiment, as shown in FIG. 6, in a manner similar to that shown in FIGS. 1-4. The angularly oriented second portion 32b of the cover panel 32 is disposed substantially directly above the heat dissipating surface 54.

Referring now to FIG. 7, an embodiment is shown that has a cover panel 32 similar to that of FIG. 5. Additionally, this embodiment includes a rear panel 30 having non-planar portions 30a, 30b similar to that of FIGS. 1-4. The cooling fan 60 is mounted so that it exhausts air that has risen above the first portion 32a, and may be mounted entirely above the first portion 32a, if desired. The angularly oriented second portion 32b of the cover panel 32 is disposed substantially directly above the heat dissipating surface 54.

Referring now to FIG. 8, another alternative embodiment is shown. This embodiment is similar to that of FIG. 7, but further includes another, angularly oriented portion 32d of the cover panel 32. An outlet 48a is positioned on the cover panel 32, similar to the embodiment of FIG. 6. The cooling fan 60 may be mounted to exhaust air that has risen above the first portion 32a, and may be mounted entirely above the first portion 32a, if desired, as shown in FIG. 8. The angularly oriented second portion 32b of the cover panel 32 is disposed substantially directly above the heat dissipating surface 54.

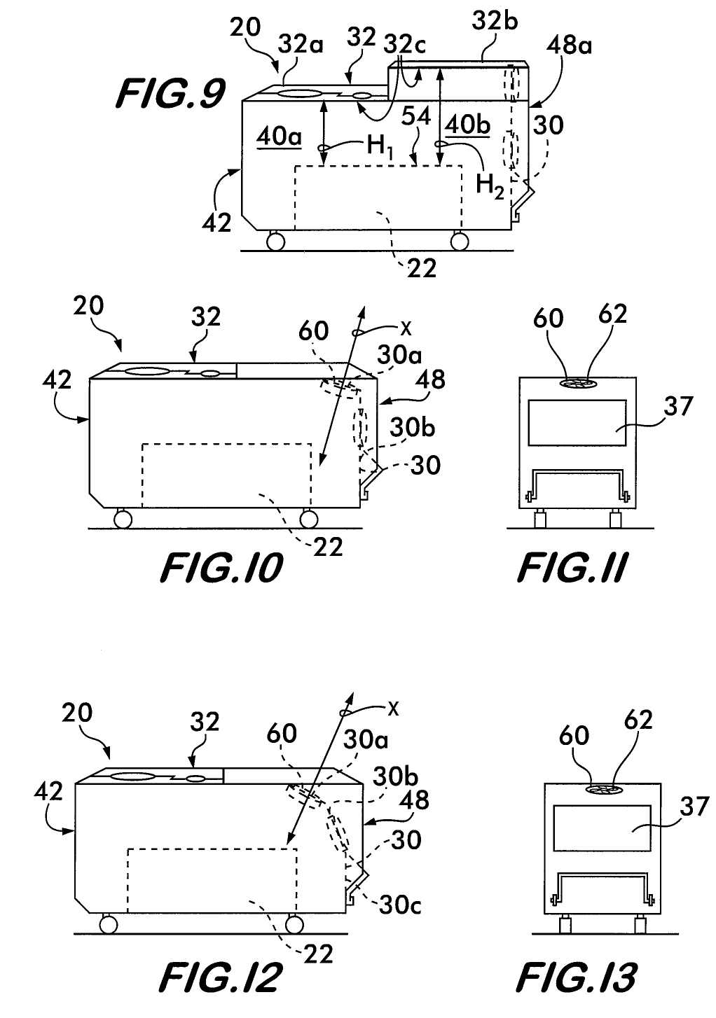

Referring now to FIG. 9, another alternative embodiment of an enclosure 20 is shown. In this embodiment, a first portion 32a of the cover panel 32 adjacent to the inlet 42 is positioned at a first height (H1) above the vacuum pump 22. The height may be measured from a reference plane above or below the pump. Accordingly, the first portion 32a defines a first space 40a having a first cross sectional area transverse to the flow path from the inlet 42 to the outlet 48. Additionally, a second portion 32b of the cover panel 32 adjacent to the outlet 48 is positioned at a second height (H2) above the vacuum pump 22. The second height H2 is greater than the first height H1. Accordingly, the second portion 32b is positioned above, or at least has a portion positioned above, the first portion 32a. The second portion 32b defines a second space 40b having a second cross sectional area transverse to the flow path that is greater than the first cross sectional area. Accordingly, cooling air admitted through the inlet 42 moves through the first space 40a at a higher speed than through the second space 40b. The elevated second portion 32b of the cover panel 32 is disposed substantially directly above the heat dissipating surface 54.

Additionally, with respect to FIG. 9, the cover panel 32 includes substantially planar first and second portions 32a, 32b, disposed in substantially parallel relation. Accordingly, an inner surface 32c of the cover panel 32 rises in step-wise fashion from the first portion 32a to the second portion 32b.

Referring now to FIGS. 10 and 11, embodiments are shown in which the cover panel 32 is not angularly oriented, but in which a cooling fan 60 has a blade 62 rotatable about an axis X angularly oriented relative to a horizontal plane. In FIG. 10, the cooling fan 60 is supported on the rear panel 30, which includes first and second substantially planar portions 30a, 30b joined at an oblique angle, similar to the rear panel 30 shown in FIGS. 1-4. In FIGS. 12 and 13, the rear panel 30 further includes a third substantially planar portion 30c joined at an oblique angle to the second substantially planar portion 30b. The angularly oriented fan may allow for better removal of heated cooling air, e.g. by mechanically augmenting the natural convective flow of the heated cooling air.

The enclosure 20 may be used for housing a pump 22 or other heat generating device by placing it within the enclosure 20, and optionally mounting it to the frame 70, and connecting the cooling fans 60, pump/device 22 and/or enclosure 20 to a power source. During operation, heat is generated by the pump, which is dissipated via the heat dissipation surfaces 54. The heat is transferred to cooling air passing through the enclosure. Even if the cooling fans 60 are not operating, convection will tend to draw cooling air from the ambient through the inlet 42 and exhaust it through the outlet 48, providing a passive cooling mode. When the fans are operating, the flow rate is increased, and cooling is enhanced, providing an active cooling mode. In either case, cooling air entering the enclosure 20 is heated as is traverses the enclosure and/or passes over the heat dissipation surfaces 54 of the pump. The heated cooling air rises by convection. The relatively higher portions of the enclosure's cover panel 32 permit the heated air to rise, away from the heat dissipation surface 54, as guided by the cover panel 32. The rising heated cooling air is replaced by cooler cooling air drawn through the inlet 42, which enhances the cooling effect. Rising heated cooling air is exhausted through the outlet 48, e.g. by a cooling fan 60. The velocity of the cooling air along a flow path from the inlet 42 toward the outlet 48 slows as the cooling air approached the outlet 48, to increase the transfer of heat by the cooling air. Further, mounting the cooling fans toward an upper boundary of the enclosure promotes rapid exhausting of the hottest cooling air. Mounting a cooling fan at an angular orientation relative to a vertical plane permits mounting of the cooling fan at a higher location in the cabinet, relative to mounting the cooling fan vertically. Use of a non-planar panel for mounting the cooling fans provides additional surface area for mounting of cooling fans, as compared with a planar panel.

The various embodiments described above are provided by way of illustration only and should not be construed to limit the invention. Those skilled in the art will readily recognize various modifications and changes that can be made to the present invention without following the examples illustrated and described herein, and without departing from the true spirit and scope of the present invention, which is set forth in the following claims.

I claim:

1. An enclosure for housing a heat-generating device, said enclosure comprising:
a plurality of body panels interconnected to surround said device;
a cover panel connected to said body panels;
an air inlet for admitting cooling air to said enclosure positioned in one of said panels;
an air outlet for exhausting cooling air from said enclosure positioned in one of said panels in spaced relation to said inlet;
an air flow path being defined by said panels between said inlet and said outlet;
at least a portion of said cover panel being angularly oriented to a horizontal plane and defining an internal space having an increasing cross sectional area transverse to said flow path between said inlet and said outlet, thereby causing air flowing into said enclosure through said inlet to change in linear velocity between said inlet and said outlet.

2. The enclosure of claim 1, wherein said cross sectional area increases toward said outlet, thereby causing air flowing into said enclosure through said inlet to slow in linear velocity as it approaches said outlet.

3. The enclosure of claim 1, wherein said outlet is positioned in said cover panel.

4. The enclosure of claim 1, wherein said cover panel is substantially planar.

5. The enclosure of claim 1, further comprising a cooling fan operable to draw cooling air through said inlet and toward said outlet, said cooling fan being supported on one of said body panels.

6. The enclosure of claim 5, wherein said one of said body panels comprises first and second substantially planar portions joined at an oblique angle, said first substantially planar portion supporting said cooling fan adjacent said outlet and toward an upper portion of said enclosure.

7. The enclosure of claim 6, further comprising a second cooling fan operable to direct a flow of air through said exhaust opening, said second substantially planar portion supporting said second cooling fan.

8. A vacuum pump assembly comprising:
said enclosure of claim 1; and
a vacuum pump, said vacuum pump being disposed within said enclosure, said vacuum pump having a heat dissipating surface, said angularly oriented portion of said cover panel being disposed substantially directly above said heat dissipating surface.

9. An enclosure for housing a heat-generating device, said enclosure comprising:
a plurality of body panels interconnected to surround said device;
an air inlet positioned in one of said body panels for admitting cooling air to said enclosure;
an air outlet positioned in another of said body panels for exhausting cooling air from said enclosure;
an air flow path defined by said panels within said enclosure between said inlet and said outlet; and
a cover panel connected to said body panels, a first portion of said cover panel adjacent to said inlet being positioned at a first height above said device and defining a first space having a first cross sectional area transverse to said flow path;
a second portion of said cover panel adjacent to said outlet being positioned at a second height above said device greater than said first height and defining a second space having a second cross sectional area transverse to said flow path greater than said first cross sectional area; wherein
cooling air admitted through said inlet moves through said first space at a higher linear speed than through said second space.

10. The enclosure of claim 9, wherein said cover panel is substantially planar.

11. The enclosure of claim 9, wherein said cover panel comprises substantially planar first and second portions disposed in substantially parallel relation, an inner surface of said cover panel rising in step-wise fashion from said first portion to said second portion.

12. The enclosure of claim 9, further comprising a cooling fan operable to draw cooling air through said inlet and toward said outlet, said cooling fan being positioned adjacent said second portion of said cover panel to exhaust air that has risen above said first portion of said cover panel.

13. The enclosure of claim 9, further comprising a cooling fan operable to draw cooling air through said inlet and toward said outlet, said cooling fan being supported on said another of said body panels.

14. The enclosure of claim 13, wherein said another of said body panels comprises first and second substantially planar portions joined at an oblique angle, said first substantially planar portion supporting said cooling fan adjacent said outlet and toward an upper portion of said enclosure.

15. The enclosure of claim 14, wherein said first substantially planar portion supports said cooling fan, and said second substantially planar portion supports a second cooling fan operable to direct a flow of air through said outlet.

16. A vacuum pump assembly comprising
said enclosure of claim 9; and
a vacuum pump, said vacuum pump being disposed within said enclosure, said vacuum pump having a heat dissipating surface, said second portion of said cover panel being disposed substantially directly above said heat dissipating surface.

17. An enclosure for housing a heat-generating device, said enclosure comprising:
a plurality of body panels interconnected to surround said device;
a cover panel connected to said body panels;
an air inlet positioned in one of said panels for admitting cooling air to said enclosure;
an air outlet positioned in another of said panels for exhausting cooling air from said enclosure; and
a cooling fan operable to draw cooling air through said inlet and toward said outlet, said cooling fan having a blade rotatable about an axis angularly oriented relative to a horizontal plane.

18. The enclosure of claim 17, wherein said cooling fan is supported on said another of said panels, said another of said panels comprising first and second substantially planar portions joined at an oblique angle, said first substantially planar portion supporting said cooling fan adjacent said outlet and toward an upper portion of said enclosure.

19. The enclosure of claim 18, wherein said second substantially planar portion supports a second cooling fan operable to direct a flow of air through said outlet.

20. The enclosure of claim 18, wherein said another of said panels further comprises a third substantially planar portion joined at an oblique angle to said second substantially planar portion.
